(19) United States
(12) Patent Application Publication
(10) Pub. No.: US 2025/0163269 A1
(43) Pub. Date: May 22, 2025

(54) RESIN COMPOSITION AND USES OF THE SAME

(71) Applicant: TAIWAN UNION TECHNOLOGY CORPORATION, ZHUBEI CITY (TW)

(72) Inventors: TSUNG-HSIEN LIN, ZHUBEI CITY (TW); SHUR-FEN LIU, ZHUBEI CITY (TW)

(73) Assignee: TAIWAN UNION TECHNOLOGY CORPORATION, ZHUBEI CITY (TW)

(21) Appl. No.: 18/426,971

(22) Filed: Jan. 30, 2024

(30) Foreign Application Priority Data
Nov. 22, 2023 (TW) 112145135

(51) Int. Cl. C08L 79/08; C08J 5/24; C08L 63/00; H05K 1/03

(52) U.S. Cl. CPC C08L 79/08; C08J 5/244; C08L 63/00; H05K 1/0366; C08J 2379/04; C08J 2425/10; C08J 2463/00; C08L 2201/02; C08L 2203/206; C08L 2205/03; C08L 2205/035; C08L 2207/04

(57) ABSTRACT

A resin composition is provided. The resin composition comprises:
(A) an epoxy resin;
(B) a maleimide-triazine resin; and
(C) a first flame retardant having a structure of formula (I):

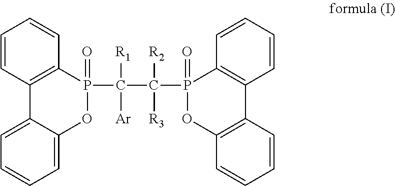

wherein,
Ar is a C₃ to C₁₈ heteroaryl or a C₆ to C₁₈ aryl;
R₁ is H or a C₁ to C₁₈ alkyl; and
R₂ and R₃ are independently H, a C₁ to C₁₈ alkyl, a C₃ to C₁₈ heteroaryl, or a C₆ to C₁₈ aryl.

### CLAIM FOR PRIORITY

This application claims the benefit of Taiwan Patent Application No. 112145135 filed on Nov. 22, 2023, the subject matters of which are incorporated herein in their entirety by reference.

### BACKGROUND OF THE INVENTION

### Field of the Invention

The present invention provides a resin composition, especially a resin composition comprising an epoxy resin, a maleimide-triazine resin, and a specific flame retardant. The resin composition of the present invention can either be used in combination with a reinforcing material to constitute a prepreg or serve as an adhesive for metal foils, facilitating the production of metal-clad laminates and printed circuit boards (PCBs).

### Descriptions of the Related Art

PCBs serve as circuit substrates in electronic devices, providing stability and electrical connections for electronic components. Traditional PCBs, known as copper-clad laminates (CCLs), consist primarily of resins, reinforcing materials and copper foils. Resins include epoxy resins, phenolic resins, polyamine formaldehyde resins, silicone, and Teflon. Reinforcing materials include glass fiber cloths, glass fiber mats, insulating papers, and linen cloths.

PCBs are typically produced by the following method: impregnating a reinforcing material, such as a glass fiber fabric, with a resin composition (such as an epoxy resin composition) and partially curing the impregnated glass fiber fabric to a half-cured state (i.e., B-stage) to obtain a prepreg; superimposing specific layers of the prepregs and superimposing a metal foil on at least one external surface of the superimposed prepregs to provide a superimposed object; hot-pressing the superimposed object (i.e., C-stage) to obtain a metal-clad laminate; etching the metal foil on the surface of the metal-clad laminate to form a defined circuit pattern; drilling a plurality of holes on the metal-clad laminate and plating these holes with a conductive material to form via holes to complete the printed circuit board.

When employing an epoxy resin composition for PCBs, flame retardants are commonly added for flame retardance, including halogen-containing flame retardants and phosphorus-containing flame retardants. Environmental concerns restrict the use of halogen-containing flame retardants. Examples of phosphorus-containing flame retardants include phosphazene compounds (such as SPB-100, available from Otsuka Chemical Co., Ltd.) or condensed phosphate esters (such as PX-200, available from Daihachi Chemical Industry Co., Ltd.). However, such flame retardants have drawbacks such as low melting points, low thermal decomposition temperatures, and high ionizability at high temperatures, leading to a high coefficient of thermal expansion and lower production yields due to inner layer cracks.

WO 2010/135398 discloses a phosphorus-containing flame retardant, which is a derivative of 9,10-dihydro-9-oxa-10-phosphaphenanthrene-10-oxide (DOPO). The derivative contains two DOPO groups (DiDOPO) per molecule and exhibits good thermal stability and flame retardance.

In addition, bismaleimide-triazine resin (BT resin) can enhance the heat resistance of the dielectric material when used as an epoxy resin substitute or additive. However, due to the polarity of imide groups in the molecular structure of bismaleimide-triazine resin, the addition of bismaleimide-triazine resin tends to compromise the water absorption resistance of the resin composition. As a result, the application of a bismaleimide-triazine resin in an epoxy resin system is limited.

Therefore, there is a need in the field for a new resin composition to address these challenges.

### SUMMARY OF THE INVENTION

Considering the aforementioned technical problems, the present invention provides a resin composition that uses an epoxy resin, a maleimide-triazine resin, and a specific flame retardant. The electronic materials prepared from the cured product of the resin composition exhibit outstanding coefficients of thermal expansion, heat resistance, dimensional stability, warpage performance, flame retardance, water absorption rate, drill wear, and peeling strength.

Therefore, an objective of the present invention is to provide a resin composition, which comprises:
(A) an epoxy resin;
(B) a maleimide-triazine resin; and
(C) a first flame retardant having a structure of formula (I):

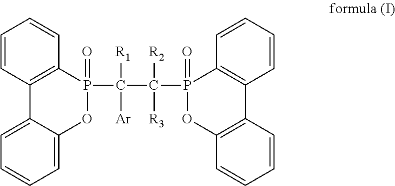

wherein,
Ar is a C₃ to C₁₈ heteroaryl or a C₆ to C₁₈ aryl;
R₁ is H or a C₁ to C₁₈ alkyl; and
R₂ and R₃ are independently H, a C₁ to C₁₈ alkyl, a C₃ to C₁₈ heteroaryl, or a C₆ to C₁₈ aryl.

In some embodiments of the present invention, the weight ratio of the first flame retardant (C) to the maleimide-triazine resin (B) is 1:6 to 5:2.

In some embodiments of the present invention, the epoxy resin (A) is selected from the group consisting of a bisphenol epoxy resin, a phenolic epoxy resin, a diphenylethylene epoxy resin, a triazine skeleton-containing epoxy resin, a fluorene skeleton-containing epoxy resin, a triphenol methane epoxy resin, a xylylene epoxy resin, a biphenyl epoxy resin, a biphenyl aralkyl epoxy resin, a naphthalene epoxy resin, a dicyclopentadiene (DCPD) epoxy resin, an alicyclic epoxy resin, and combinations thereof.

In some embodiments of the present invention, the maleimide-triazine resin (B) is obtained by reacting a maleimide compound with a cyanate ester compound.

The maleimide compound is preferably a bismaleimide compound.

The cyanate ester compound is preferably a compound having two or more cyanate groups, even more preferable is an aromatic compound having two or more cyanate groups directly bonded to aromatic ring(s). The aforementioned cyanate ester compounds can be used alone or in combination.

In some embodiments of the present invention, the first flame retardant (C) is selected from the group consisting of

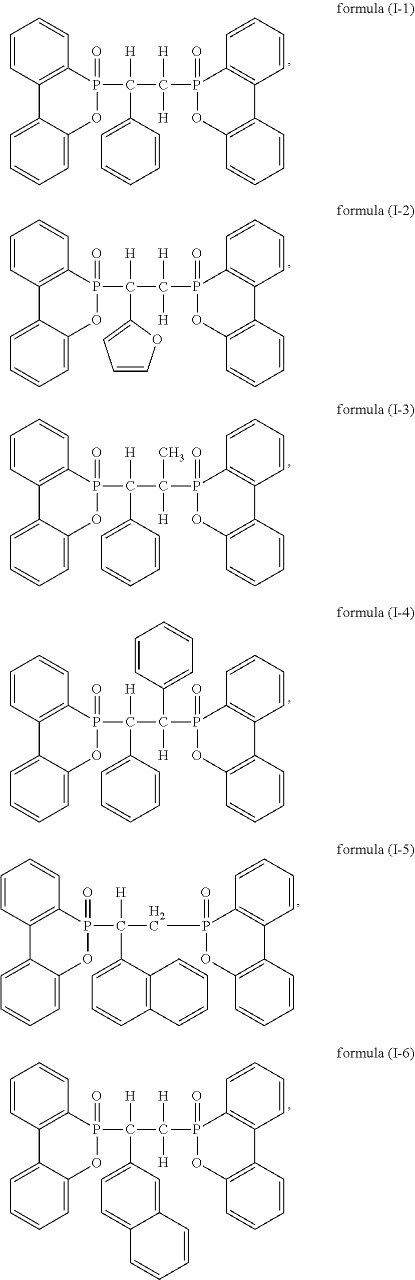

and combinations thereof.

In some embodiments of the present invention, the resin composition further comprises a curing agent selected from the group consisting of a cyanate ester resin, a benzoxazine resin, a phenol novolac (PN) resin, a styrene maleic anhydride (SMA) resin, dicyandiamide (Dicy), diaminodiphenyl sulfone (DDS), an amino triazine novolac (ATN) resin, diaminodiphenylmethane, a styrene-vinylphenol copolymer, and combinations thereof.

In some embodiments of the present invention, the resin composition further comprises a curing accelerator selected from the group consisting of an imidazole compound, a pyridine compound, and a combination thereof.

In some embodiments of the present invention, the resin composition further comprises an elastomer selected from the group consisting of polybutadiene, a styrene-butadiene copolymer, a styrene-butadiene-divinylbenzene copolymer, polyisoprene, a styrene-isoprene copolymer, an acrylonitrile-butadiene copolymer, an acrylonitrile-butadiene-styrene copolymer, a functional modified derivative of the preceding compounds, and combinations thereof.

In some embodiments of the present invention, the resin composition further comprises a filler selected from the group consisting of silica, aluminum oxide, magnesium oxide, magnesium hydroxide, calcium carbonate, talc, clay, aluminum nitride, boron nitride, aluminum hydroxide, silicon aluminum carbide, silicon carbide, sodium carbonate, titanium dioxide, zinc oxide, zirconium oxide, quartz, diamond, diamond-like carbon, graphite, calcined kaolin, pryan, mica, hydrotalcite, polytetrafluoroethylene (PTFE) powders, glass beads, ceramic whiskers, carbon nanotubes, nanosized inorganic powders, and combinations thereof.

Another objective of the present invention is to provide a prepreg, which is prepared by impregnating a substrate with the aforementioned resin composition or by coating the aforementioned resin composition onto a substrate and drying the impregnated or coated substrate.

Another objective of the present invention is to provide a metal-clad laminate prepared by laminating the aforementioned prepreg and a metal foil or by coating the aforementioned resin composition onto a metal foil and drying the coated metal foil.

Another objective of the present invention is to provide a printed circuit board prepared from the aforementioned metal-clad laminate.

To render the above objectives, technical features, and advantages of the present invention more apparent, the present invention will be described in detail with reference to some embodiments hereinafter.

### BRIEF DESCRIPTION OF THE DRAWINGS

Not applicable.

### DESCRIPTION OF THE PREFERRED EMBODIMENTS

Hereinafter, some embodiments of the present invention will be described in detail. However, the present invention may be embodied in various embodiments, and the protection scope of the present invention should not be limited to those described in the specification.

Unless otherwise specified, the expressions “a,” “the,” or the like recited in the specification and the claims should include both the singular and the plural forms.

Unless otherwise specified, when detailing the amounts of components in a solution, mixture, or composition in the specification and the claims, it is calculated based on the total weight excluding the solvent.

Unless otherwise specified, the terms “first,” “second,” or similar expressions used in the specification and claims are employed solely for the purpose of distinguishing the depicted elements or components without any specific significance. Those terms are not intended to imply priority.

Unless otherwise specified, the specified range's endpoint is encompassed when describing a numeral range using terms like “or more,” “or less,” or similar expressions in the specification and claims. For example, the phrase “two or more” is inclusive of the value two and any greater values.

Utilizing an epoxy resin (A), a maleimide-triazine resin (B), and a specific flame retardant (C), the cured product of the resin composition of the present invention yields electronic materials prepared with an excellent coefficient of thermal expansion, heat resistance, dimensional stability, warpage performance, flame retardance, water absorption rate, drill wear, and peeling strength. Detailed descriptions of the resin composition of the present invention and its applications follow below.

### 1. Resin Composition

The resin composition of the present invention comprises (A) an epoxy resin, (B) a maleimide-triazine resin, and (C) a first flame retardant having a specific structure as essential components. Additionally, optional components may be included. Detailed descriptions of these components are provided below.

### 1.1. (A) Epoxy Resin

In the present invention, an epoxy resin refers to a thermosetting resin containing at least two epoxy functional groups in a single molecule, such as polyfunctional epoxy resins and phenolic epoxy resins. Examples of polyfunctional epoxy resins include but are not limited to, bifunctional epoxy resins, tetrafunctional epoxy resins, and octafunctional epoxy resins. The choice of epoxy resin for the present invention is not limited and can be determined by persons having ordinary skills in the art based on the disclosure of the subject specification and specific requirements. For example, a bromine-containing epoxy resin may enhance the flame retardance properties of the thermosetting resin composition. Alternatively, a halogen-free (e.g., bromine-free) epoxy resin may be used to meet environmentally friendly criteria.

Examples of epoxy resin include but are not limited to, a bisphenol epoxy resin, a phenolic epoxy resin, a diphenylethylene epoxy resin, a triazine skeleton-containing epoxy resin, a fluorene skeleton-containing epoxy resin, a triphenol methane epoxy resin, a xylylene epoxy resin, a biphenyl epoxy resin, a biphenyl aralkyl epoxy resin, a naphthalene epoxy resin, dicyclopentadiene (DCPD) epoxy resin, and an alicyclic epoxy resin. Examples of bisphenol epoxy resin include but are not limited to bisphenol A epoxy resin, bisphenol F epoxy resin, and bisphenol S epoxy resin. Examples of phenolic epoxy resin (e.g., linear phenolic epoxy resin) include but are not limited to, phenol phenolic epoxy resin, methylphenol phenolic epoxy resin, bisphenol A phenolic epoxy resin, and bisphenol F phenolic epoxy resin. Examples of epoxy resin also include the diglycidyl ether compounds of polyfunctional phenol and polycyclic aromatic compounds such as anthracene.

The aforementioned epoxy resins can be used alone or in any combination, depending on the need. In some embodiments of the present invention, bisphenol A epoxy resin, a phenolic epoxy resin, or a combination thereof is used.

In the resin composition of the present invention, based on the total weight of the resin composition, the amount of the epoxy resin can be 3 wt % to 15 wt %. For example, based on the total weight of the resin composition, the amount of the epoxy resin can be 3 wt %, 4 wt %, 5 wt %, 6 wt %, 7 wt %, 8 wt %, 9 wt %, 10 wt %, 11 wt %, 12 wt %, 13 wt %, 14 wt %, or 15 wt %, or within a range between any two of the values described herein, but the present invention is not limited thereto.

### 1.2. (B) Maleimide-Triazine Resin

A maleimide-triazine resin has reactive functional group(s) capable of participating in a cross-linking reaction with other components having unsaturated functional group(s) or epoxy group(s).

The maleimide-triazine resin (B) can be synthesized by reacting a maleimide compound with a cyanate ester compound. For example, the maleimide-triazine resin can be prepared under solvent-free conditions by heating the maleimide compound and the cyanate ester compound until they reach a molten state, thoroughly mixing them, and performing polymerization. Alternatively, the maleimide-triazine resin can be prepared by dissolving the maleimide compound and the cyanate ester compound in a suitable organic solvent and performing polymerization. Examples of suitable solvents include but are not limited to, methyl ethyl ketone, N-methylpyrrolidinone, dimethylformamide, dimethylacetamide, toluene, and xylene.

The type of maleimide compound is not limited and can be any compound having one

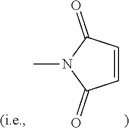

or more maleimide group(s) in a single molecule. Based on the number of maleimide group(s) contained in a single molecule, maleimide compounds can be categorized into monomaleimide compounds with one maleimide group in a single molecule and polyfunctional maleimide compounds with two or more maleimide groups in a single molecule. In some embodiments of the present invention, the maleimide compound is preferably a polyfunctional maleimide compound, such as a bismaleimide compound with two maleimide groups in a single molecule.

Examples of monomaleimide compounds include, but are not limited to, N-phenylmaleimide and N-hydrophenylmaleimide.

The bismaleimide compound can have a structure of

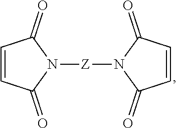

wherein Z can be selected from the group consisting of methylene (—CH₂—), 4,4′-diphenylmethyl

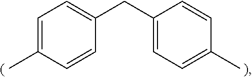

m-phenylene

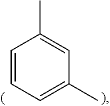

bisphenol A diphenyl ether group

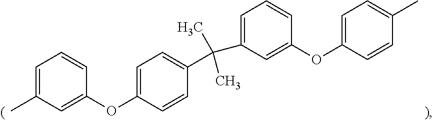

3,3′-dimethyl-5,5′-diethyl-4,4′-diphenylmethane group

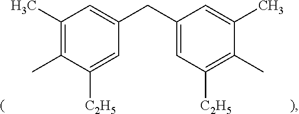

4-methyl-1,3-phenylene

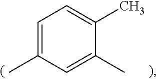

and (2,2,4-trimethyl)-1,6-hexamethylene

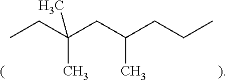

Specific examples of the bismaleimide compound include, but are not limited to, 1,2-bismaleimidoethane, 1,6-bismaleimidohexane, 1,3-bismaleimidobenzene, 1,4-bismaleimidobenzene, 2,4-bismaleimidotoluene, 4,4′-bismaleimidodiphenylmethane, 4,4′-bismaleimidodiphenyl ether, 3,3′-bismaleimidodiphenyl sulfone, 4,4′-bismaleimidodiphenyl sulfone, 4,4′-bismaleimidodicyclohexyl methane, 3,5-bis(4-maleimidophenyl)pyridine, 2,6-bismaleimidopyridine, 1,3-bis(maleimidomethyl)cylcohexane, 1,3-bis(maleimidomethyl)benzene, 1,1-bis(4-maleimidophenyl)cyclohexane, 1,3-bis(dichloromaleimido)benzene, 4,4′-biscitraconimidodiphenylmethane, 2,2-bis(4-maleimidophenyl)propane, 1-phenyl-1,1-bis(4-maleimidophenyl)ethane, α,α-bis(4-maleimidophenyl)toluene, 3,5-bismaleimido-1,2,4-triazole, N,N′-ethylenebismaleimide, N,N′-hexamethylenebismaleimide, N,N′-m-phenylenebismaleimide, N,N′-p-phenylenebismaleimide, N,N′-4,4′-diphenylmethane bismaleimide, N,N′-4,4′-diphenyl ether bismaleimide, N,N′-4,4′-diphenylsulfone bismaleimide, N,N′-4,4′-dicyclohexylmethane bismaleimide, N,N′-α,α′-4,4′-dimethylene cyclohexane bismaleimide, N,N′-m-dimethylphenylbismaleimide, N,N′-4,4′-diphenylcyclohexane bismaleimide, and N,N′-methylene bis(3-chloro-p-phenylene)bismaleimide.

When preparing the maleimide-triazine resin (B), the aforementioned maleimide compounds can be used alone or in any combination, and they can be used in the form of monomers, oligomers, or polymers.

The type of the cyanate ester compound is not limited as long as its molecule contains cyanate ester group(s) (i.e., —O—C≡N). In some embodiments of the present invention, the cyanate ester compound is preferably a compound having two or more cyanate groups, preferably an aromatic compound having two or more cyanate groups directly bonded to aromatic ring(s).

The cyanate ester compound can be obtained by substituting hydroxyl group(s) of a hydroxyl-containing compound with cyanate ester group(s). Examples of the hydroxyl-containing compound include, but are not limited to, bisphenol A, bisphenol F, bisphenol M, bisphenol P, bisphenol E, a phenol novolak resin, a cresol novolak resin, a dicyclopentadiene novolak resin, tetramethyl bisphenol F, a bisphenol A novolak resin, brominated bisphenol A, a brominated phenol novolak resin, a trifunctional phenol, a tetrafunctional phenol, a naphthalene phenol, a biphenyl phenol, a phenol aralkyl resin, a biphenyl aralkyl resin, a naphthol aralkyl resin, a dicyclopentadiene aralkyl resin, an alicyclic phenol, and a phosphorus-containing phenol. Therefore, examples of the cyanate ester compound include, but are not limited to, compounds obtained by substituting hydroxyl group(s) of the aforementioned hydroxyl-containing compounds with cyanate ester group(s).

When preparing the maleimide-triazine resin (B), the aforementioned cyanate ester compounds can be used alone or in any combination, and they can be used in the form of monomers, oligomers, or polymers.

In some embodiments of the present invention, the maleimide-triazine resin (B) is a bismaleimide-triazine resin, which can be prepared by reacting a maleimide compound with a cyanate ester compound or obtained commercially. Commercially available maleimide-triazine resins include Nanozine 520 and Nanozine 600, available from Namokor Company, and BT-2100, BT-2170, BT-2160L, BT-2160, and BT-2164, available from Mitsubishi Gas Chemical Company. In the resin composition of the present invention, the aforementioned maleimide-triazine resins can be used alone or in any combination, and persons having ordinary skills in the art can make adjustments depending on the need. In some embodiments of the present invention, Nanozine 520, BT-2100, or a combination thereof is used.

In the resin composition of the present invention, based on the total weight of the resin composition, the amount of the maleimide-triazine resin can be 5 wt % to 30 wt %. For example, based on the total weight of the resin composition, the amount of the maleimide-triazine resin can be 5 wt %, 6 wt %, 7 wt %, 8 wt %, 9 wt %, 10 wt %, 11 wt %, 12 wt %, 13 wt %, 14 wt %, 15 wt %, 16 wt %, 17 wt %, 18 wt %, 19 wt %, 20 wt %, 21 wt %, 22 wt %, 23 wt %, 24 wt %, 25 wt %, 26 wt %, 27 wt %, 28 wt %, 29 wt %, or 30 wt %, or within a range between any two of the values described herein, but the present invention is not limited thereto.

### 1.3. (C) First Flame Retardant

Generally, flame retardants can improve flame retardance. As used herein, the first flame retardant is a compound with a specific structure of the following formula (I):

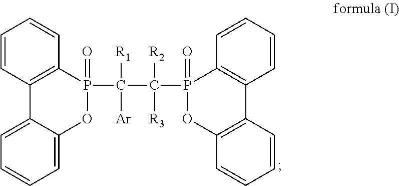

and
in formula (I), Ar is a C₃ to C₁₈ heteroaryl or a C₆ to C₁₈ aryl; R₁ is H or a C₁ to C₁₈ alkyl; and R₂ and R₃ are independently H, a C₁ to C₁₈ alkyl, a C₃ to C₁₈ heteroaryl, or a C₆ to C₁₈ aryl. The C₃ to C₁₈ heteroaryl refers to an aromatic cyclic or fused cyclic structure with 3 to 18 carbon atoms, incorporating one or more heteroatoms (e.g., O, N, and S) within one or more aromatic rings or fused rings. The C₆ to C₁₈ aryl refers to an aromatic monocyclic, polycyclic, or fused cyclic structure with 6 to 18 carbon atoms. Examples of the C₃ to C₁₈ heteroaryl include, but are not limited to, pyridyl, furyl, and imidazolyl. Examples of the C₆ to C₁₈ aryl include, but are not limited to, phenyl, naphthyl, and anthryl. Examples of C₁ to C₁₈ alkyl include, but are not limited to, methyl, ethyl, n-propyl, isopropyl, n-butyl, and isobutyl. The Ar moiety of the first flame retardant is preferably phenyl, naphthyl, or anthryl, more preferably phenyl or naphthyl, and even more preferably phenyl. Meeting these conditions enhances the properties of the material prepared from the resin composition, including the coefficient of thermal expansion, heat resistance, dimensional stability, warpage performance, water absorption rate, and peeling strength.

Examples of the first flame retardant (C) include, but are not limited to,

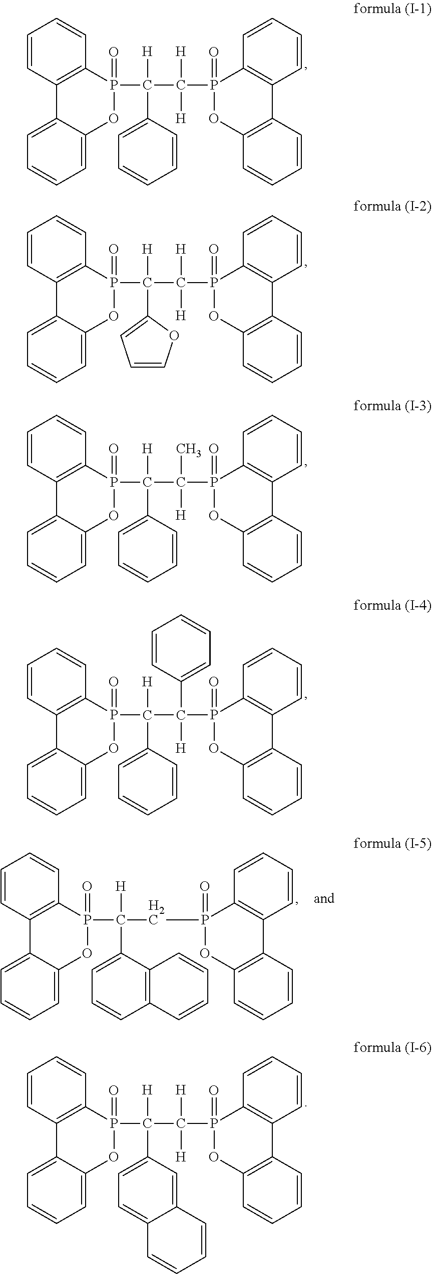

In some embodiments of the present invention, the first flame retardant (C) is a flame retardant having a structure of formula (I-1), a flame retardant having a structure of formula (I-2), or combination thereof.

Compared with other DOPO-based flame retardants, the first flame retardant used in the present invention comprises an aryl-substituted ethylene group as a bridging group. Without being bound by any theory, it is believed that the first flame retardant (C) exhibits good stiffness due to the short chain of the bridging group. Additionally, the aryl substituent on the ethylene group provides enhanced steric hindrance, contributing to good chemical stability and low volatility of the first flame retardant (C). Consequently, the material prepared from the resin composition of the present invention exhibits improved flame retardance.

Furthermore, the inventor of the present invention discovered an unexpected synergistic effect between the first flame retardant (C) and the maleimide-triazine resin (B). This combination mitigates the problem of poor water absorption typically associated with the addition of bismaleimide-triazine resin in an epoxy resin system while ensuring excellent laminate properties.

The weight ratio of the first flame retardant (C) to the maleimide-triazine resin (B) is preferably 1:6 to 5:2. For example, the weight ratio of the first flame retardant (C) to the maleimide-triazine resin (B) can be 1:6, 2:11, 1:5, 2:9, 1:4, 2:7, 1:3, 2:5, 1:2, 2:3, 1:1, 3:2, 2:1, or 5:2, or within a range between any two of the values described herein. When the weight ratio of the first flame retardant (C) to the maleimide-triazine resin (B) is within the aforementioned range, the electronic material prepared from the resin composition can have further improved drill wear and water absorption rate.

### 1.3. Optional Components

In addition to the aforementioned components, the resin composition of the present invention may further comprise optional components to improve specific physicochemical properties of the material prepared from the resin composition or to improve the processibility of the resin composition. The optional components can encompass various conventional additives known in the art, such as curing agents, curing accelerators, elastomers, fillers, dispersing agents, tougheners, viscosity modifiers, flame retardants (excluding the first flame retardant (C)), plasticizers, coupling agents, and more. The additives do not constitute the core aspect of the present invention. They can be carried out by persons having ordinary skills in the art based on the disclosure of the subject specification and their skill level. The subsequent paragraphs elaborate on the optional components, focusing on curing agents, curing accelerators, elastomers, and fillers.

### 1.3.1. Curing Agent

The resin composition of the present invention can further comprise a curing agent. The curing agent can be any conventional curing agent suitable for an epoxy resin, including hydroxyl-containing compounds, amino-containing compounds, anhydride compounds, and active ester compounds. Examples of the curing agent include, but are not limited to, a cyanate ester resin, a benzoxazine resin, a phenol novolac (PN) resin, a phenolic novolac resin, a styrene maleic anhydride (SMA) resin, dicyandiamide (Dicy), diaminodiphenyl sulfone (DDS), an amino triazine novolac (ATN) resin, diaminodiphenylmethane, and styrene-vinylphenol copolymer. The aforementioned curing agents can be used alone or in any combination. In some embodiments of the present invention, a phenolic novolac resin, a benzoxazine resin, or a combination thereof is used.

Based on the total weight of the resin composition, the amount of the curing agent can be 0 wt % to 15 wt %. For example, based on the total weight of the resin composition, the amount of the curing agent can be 1 wt %, 2 wt %, 3 wt %, 4 wt %, 5 wt %, 6 wt %, 7 wt %, 8 wt %, 9 wt %, 10 wt %, 11 wt %, 12 wt %, 13 wt %, 14 wt %, or 15 wt %, or within a range between any two of the values described herein, but the present invention is not limited thereto.

### 1.3.2. Curing Accelerator

The resin composition of the present invention can further comprise a curing accelerator. The curing accelerator can promote the reaction of epoxy functional groups and lower the curing reaction temperature of the resin composition. The curing accelerator can be any substance that can promote the ring-opening reaction of epoxy functional groups and lower the curing reaction temperature. Examples of the curing accelerator include tertiary amines, quaternary amines, imidazole-based compounds, and pyridine-based compounds. The aforementioned curing accelerators can be used alone or in any combination. In some embodiments of the present invention, the curing accelerator is an imidazole compound, a pyridine compound, or a combination thereof. Examples of the imidazole compound include, but are not limited to, 2-methyl-imidazole (2 MI), 2-ethyl-4-methyl-imidazole (2E4MZ), and 2-phenyl-imidazole (2PI). Examples of the pyridine compound include, but are not limited to, 2,3-diaminopyridine, 2,5-diaminopyridine, 2,6-diaminopyridine, 4-dimethylaminopyridine, 2-amino-3-methylpyridine, 2-amino-4-methylpyridine, and 2-amino-3-nitropyridine. In some embodiments of the present invention, 2-phenyl-imidazole and 2-ethyl-4-methyl-imidazole, or a combination thereof is used.

Based on the total weight of the resin composition, the amount of the curing accelerator can be 0.01 wt % to 0.6 wt %. For example, based on the total weight of the resin composition, the amount of the curing accelerator can be 0.01 wt %, 0.05 wt %, 0.10 wt %, 0.15 wt %, 0.20 wt %, 0.25 wt %, 0.30 wt %, 0.35 wt %, 0.40 wt %, 0.45 wt %, 0.50 wt %, 0.55 wt %, or 0.60 wt %, or within a range between any two of the values described herein, but the present invention is not limited thereto.

### 1.3.3. Elastomer

The resin composition of the present invention can further comprise an elastomer to improve the toughness of the electronic material prepared from the resin composition. Examples of elastomer include, but are not limited to, polybutadiene, a styrene-butadiene copolymer, a styrene-butadiene-divinylbenzene copolymer, polyisoprene, a styrene-isoprene copolymer, an acrylonitrile-butadiene copolymer, an acrylonitrile-butadiene-styrene copolymer, and a functional modified derivative of the preceding compounds. Examples of the functional modified derivative include but are not limited to, a maleic anhydride-modified polybutadiene and a maleic anhydride-modified polybutadiene-styrene copolymer. The aforementioned elastomers can be used alone or in any combination. In some embodiments of the present invention, a styrene-butadiene copolymer is used.

Based on the total weight of the resin composition, the amount of the elastomer can be 0 wt % to 10 wt %. For example, based on the total weight of the resin composition, the amount of the elastomer can be 1 wt %, 2 wt %, 3 wt %, 4 wt %, 5 wt %, 6 wt %, 7 wt %, 8 wt %, 9 wt %, or 10 wt %, or within a range between any two of the values described herein, but the present invention is not limited thereto.

### 1.3.4. Filler

The resin composition of the present invention can further comprise a filler to improve the dimensional stability of the electronic materials prepared from the resin composition. Examples of the filler include, but are not limited to, organic or inorganic fillers selected from the group consisting of silica (including solid silica and hollow silica), aluminum oxide, magnesium oxide, magnesium hydroxide, calcium carbonate, talc, clay, aluminum nitride, boron nitride, aluminum hydroxide, silicon aluminum carbide, silicon carbide, sodium carbonate, titanium dioxide, zinc oxide, zirconium oxide, quartz, diamond, diamond-like carbon, graphite, calcined kaolin, pryan, mica, hydrotalcite, polytetrafluoroethylene (PTFE) powders, glass beads, ceramic whiskers, carbon nanotubes, and nanosized inorganic powders. The fillers can be used alone or in any combination. In some embodiments of the present invention, a silica filler is used.

Based on the total weight of the resin composition, the amount of the filler can be 40 wt % to 50 wt %. For example, based on the total weight of the resin composition, the amount of the filler can be 40 wt %, 41 wt %, 42 wt %, 43 wt %, 44 wt %, 45 wt %, 46 wt %, 47 wt %, 48 wt %, 49 wt %, or 50 wt %, or within a range between any two of the values described herein, but the present invention is not limited thereto.

### 1.4. Preparation of Resin Composition

The resin composition of the present invention can be prepared into a varnish by thoroughly blending the components of the resin composition, including the epoxy resin (A), the maleimide-triazine resin (B), the first flame retardant (C), and other optional components, with a stirrer, and dissolving or dispersing the resultant mixture in a solvent. The solvent can be any inert solvent that can dissolve or disperse the components of the resin composition but does not react with the components of the resin composition. Examples of the inert solvent include but are not limited to toluene, γ-butyrolactone, methyl ethyl ketone, cyclohexanone, butanone, acetone, xylene, methyl isobutyl ketone, N,N-dimethylformamide (DMF), N,N-dimethylacetamide (DMAc), and N-methylpyrolidone (NMP). The aforementioned solvents can be used alone or in combination. The solvent content in the resin composition is not limited as long as the components of the resin composition can be evenly dissolved or dispersed therein. In some embodiments of the present invention, a mixture of methyl ethyl ketone and N,N-dimethylacetamide is used as a solvent.

### 2. Prepreg

The present invention also provides a prepreg prepared from the aforementioned resin composition, wherein the prepreg is prepared by impregnating a substrate with the aforementioned resin composition or by coating the aforementioned resin composition onto a substrate and drying the impregnated or coated substrate. Examples of the substrate include but are not limited to, papers, cloths, or mats made from a material selected from the group consisting of paper fibers, glass fibers, quartz fibers, organic polymer fibers, carbon fibers, and combinations thereof. Examples of the organic polymer fibers include, but are not limited to, high-modulus polypropylene (HMPP) fibers, polyamide fibers, fibers of ultra-high molecular weight polyethylene (UHMWPE), and liquid crystal polymer fibers. The cloths made from the material selected from the aforementioned group can be woven or non-woven. In some embodiments of the present invention, 2116 reinforced glass fabric is used as a reinforcing material, and the resin composition is heated and dried at 175° C. for 2 to 15 minutes (B-stage) to prepare a semi-cured prepreg.

### 3. Metal-Clad Laminate and Printed Circuit Board

The present invention also provides a metal-clad laminate, which can be obtained by laminating the aforementioned prepreg with metal foil(s). For example, the metal-clad laminate can be obtained by superimposing a plurality of the aforementioned prepregs as the dielectric layer, superimposing a metal foil (such as a copper foil) as the metal layer on at least one external surface of the dielectric layer to provide a superimposed object, and then subjecting the superimposed object to hot-pressing to obtain the metal-clad laminate. Alternatively, the metal-clad laminate can be prepared by directly coating the aforementioned resin composition on a metal foil and drying the coated metal foil.

The external metal foil of the metal-clad laminate can also undergo patterning to form a printed circuit board.

### 4. EXAMPLES

### 4.1. Testing Methods

The present invention is further illustrated by the embodiments hereinafter, wherein the testing instruments and methods are as follows.

[Coefficient of Thermal Expansion (z-CTE) Test]

A thermal mechanical analyzer (TMA) is used to measure the coefficient of thermal expansion (z-CTE) of the fully cured resin composition in the Z-direction (in the thickness direction of the substrate). The testing method includes the following steps: preparing a fully cured resin composition sample sized at 5 mm×5 mm×1.5 mm; setting the conditions as follows: a starting temperature of 30° C., an end temperature of 330° C., a heating rate of 10° C./min, and a load of 0.05 Newton (N); subjecting the sample to thermomechanical analysis under the specified conditions in expansion/compression mode; and measuring the thermal expansion values per 1° C. within the range of 30° C. to 330° C., and then averaging the measured values. The unit of the z-CTE is “%.”

### [Heat Resistance (T288) Test]

Six prepregs and a copper foil are laminated to provide a copper-clad laminate sample sized at 6.5 mm in length×6.5 mm in width. The test is conducted following IPC-TM-650 2.4.24.1 using a thermal mechanical analyzer (TMA) at 288° C., and the duration until the copper-clad laminate delaminates is recorded. A longer duration before delamination indicates higher heat resistance of the copper-clad laminate. If delamination still does not occur within 60 minutes, the result is recorded as “>60”, meaning that the T288 heat resistance test can endure over 60 minutes without delamination.

### [Dimensional Stability Test]

A copper-clad laminate for evaluation is cut into a size of 12 inches×11 inches, subjected to drilling, and then etched to remove the copper foils at both sides, resulting in an unclad laminate sample with holes. The sample undergoes testing according to IPC-TM-650 2.4.39 by being baked in an oven at 105° C. for 4 hours, followed by baking at 150° C. for 2 hours. The dimensional variation of the sample in machine direction is then measured. The unit of dimensional variation is ppm/° C.

### [Warpage Test]

The warpage test is conducted according to IPC-TM-650-2.4.22 by subjecting the metal-clad laminate to one-side etching, observing the bending of the etched laminate, and calculating the bending rate.

### [Flame Retardance Test]

The flame retardance test is performed according to UL94V (Vertical Burn). The copper-clad laminate is held vertically and exposed to a Bunsen burner to assess its self-extinguishing and comburent properties. The flame retardance levels are ranked as V0>V1>V2.

### [Water Absorption Test]

The weight (W1) of the copper-clad laminate sample is measured. Subsequently, the copper-clad laminate is placed in a container and subjected to a pressure cooker test (PCT) under the following conditions: 121° C., 100% relative humidity (R.H.), 1.2 atm, for a 2-hour duration. After moisture absorption, the weight (W2) is measured. The water absorption rate of the copper-clad laminate is calculated according to the following equation.

$$Water absorption rate = [ ( W 2 - W 1 ) / W 1 ] \times 100 \%$$

### [Drill Wear Test]

The drill wear is tested by subjecting the copper-clad laminate to repeated drilling using a 0.3 mm diameter drill, performing 2000 times, and observing the wear on the drill's top surface. Since the cutting edge (CE) of the drill comes into continuous contact with the copper-clad laminate, it experiences wear, particularly on the cutting corner (CC) of the cutting edge (CE). In this test, the wear percentage of the drill is determined by measuring the wear percentage of the cutting corner (CC).

### [Peeling Strength Test]

The peeling strength refers to the adhesion between the metal foil and the hot-pressed laminated prepreg. The peeling strength is expressed by the force required to vertically peel off a ⅛-inch-wide copper foil (0.5 oz.) from the laminate. The unit of the peel strength is lbf/in.

### 4.2. List of Raw Materials Used in Examples and Comparative Examples

| Raw material | Description | |
|---|---|---|
| BNE-210 | Bisphenol A epoxy resin, with a solid content of 80%, | |
| | available from CCP Company | |
| PNE-177 | Phenolic epoxy resin, with a solid content of 75%, | |
| | available from CCP Company | |
| Nanozine 520 | Bismaleimide-triazine resin, with a solid content of | |
| | 60%, available from Nanokor Company | |
| BT-2100 | Bismaleimide-triazine resin, with a solid content of 60%, | |
| | available from Mitsubishi Gas Chemical Company | |
| Compound of | Flame retardant with a structure represented by | |
| formula (I-1) | | |
| | 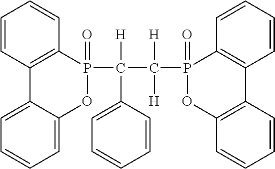 [SMILES: O=P1(CC(c2ccccc2)P2(=O)Oc3ccccc3-c3ccccc32)Oc2ccccc2-c2ccccc21] | formula (I-1) |
| Compound of | Flame retardant with a structure represented by | |
| formula (I-2) | | |
| | 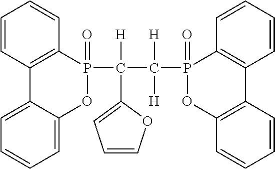 [SMILES: O=P1(CC(c2ccco2)P2(=O)Oc3ccccc3-c3ccccc32)Oc2ccccc2-c2ccccc21] | formula (I-2) |
| SPB-100 | Flame retardant, available from Otsuka Chemical Company | |
| XZ92741 | Flame retardant, available from Blue Cube Company | |
| Compound of | Flame retardant with a structure represented by | |
| formula (II-1) | | |
| | 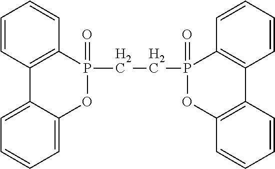 [SMILES: O=P1(CCP2(=O)Oc3ccccc3-c3ccccc32)Oc2ccccc2-c2ccccc21] | formula (II-1) |

| | |
|---|---|
| PF-8110 | Curing agent, phenolic novolac resin, with a solid content of 65%, available |
| | from CCP Company |
| LZ8290 | Curing agent, benzoxazine resin, with a solid content of 65%, available |
| | from Huntsman Company |
| 2PI | Curing accelerator, available from Shikoku Chemicals Company |
| 2E4MZ | Curing accelerator, available from Sigma-Aldrich Company |
| Ricon 100 | Elastomer, styrene-butadiene copolymer, available from Cray Valley |
| | Company |
| Ricon 184MA6 | Elastomer, maleic anhydride-modified styrene-butadiene copolymer, |
| | available from Cray Valley Company |
| 525ARI | SiO₂ filler, available from Sibelco Company |
| L19 | SiO₂ filler, available from Suzhou Ginet New Material Technology |
| | Company |

### 4.3. Preparation of Resin Composition

According to the components and amounts shown in Table 1 and Table 2, the components were mixed with methyl ethyl ketone and cyclohexanone (both available from Methyl Company) using a stirrer at room temperature. The resulting mixture was stirred at room temperature for 60 to 120 minutes to obtain the resin compositions of Examples E1 to E12 and Comparative Examples CE1 to CE6.

TABLE 1

| Unit: added parts by | | | | | | | | | | | | | |
|---|---|---|---|---|---|---|---|---|---|---|---|---|---|
| weight | | E1 | E2 | E3 | E4 | E5 | E6 | E7 | E8 | E9 | E10 | E11 | E12 |
| Epoxy | BNE-210 | 10 | 5 | 5 | 5 | | 5 | | | | 15 | 10 | 10 |
| resin | PNE-177 | | | | | 5 | | 5 | 5 | 15 | | | |
| Maleimide- | Nanozine | 35 | 25 | 30 | 25 | | 20 | | 35 | 20 | 15 | 25 | 25 |
| triazine | 520 | | | | | | | | | | | | |
| resin | BT-2100 | | 10 | | | 20 | | 30 | | | | | |
| Flame | Compound | 5 | 10 | 15 | 20 | 25 | 15 | 10 | 10 | 5 | 15 | | 12 |
| retardant | of | | | | | | | | | | | | |
| | formula | | | | | | | | | | | | |
| | (I-1) | | | | | | | | | | | | |
| | Compound | | | | | | | | | | | 12 | |
| | of | | | | | | | | | | | | |
| | formula | | | | | | | | | | | | |
| | (I-2) | | | | | | | | | | | | |
| | SPB-100 | | | | | | | | | | | | |
| | XZ92741 | | | | | | | | | | | | |
| | Compound | | | | | | | | | | | | |
| | of | | | | | | | | | | | | |
| | formula | | | | | | | | | | | | |
| | (II-1) | | | | | | | | | | | | |
| Curing | PF-8110 | | | | | | | | | 5 | | | |
| agent | LZ8290 | 5 | 5 | 5 | 5 | 5 | 15 | 5 | 5 | | | | 10 |
| Curing | 2PI | 0.1 | 0.01 | 0.2 | 0.5 | 0.02 | 0.05 | 0.05 | 0.05 | | | | |
| accelerator | 2E4MZ | | | | | | | | | 0.05 | 0.05 | 0.1 | 0.1 |
| Elastomer | Ricon | 5 | 5 | 5 | 5 | 5 | | | | | 15 | 13 | 3 |
| | 100 | | | | | | | | | | | | |
| | Ricon | | | | | | 5 | 10 | 5 | 15 | | | |
| | 184MA6 | | | | | | | | | | | | |
| Filler | 525ARI | 40 | 40 | 40 | 40 | 40 | 40 | 40 | 40 | | | | |
| | L19 | | | | | | | | | 40 | 40 | 40 | 40 |

TABLE 2

| Unit: added parts by weight | | CE1 | CE2 | CE3 | CE4 | CE5 | CE6 |
|---|---|---|---|---|---|---|---|
| Epoxy resin | BNE-210 | | 5 | 5 | 5 | 5 | 5 |
| | PNE-177 | | | | | | |
| Maleimide- | Nanozine 520 | 30 | | 30 | 30 | 30 | 30 |
| triazine resin | BT-2100 | | | | | | |
| Flame | Compound of | 15 | 15 | | | | |
| retardant | formula (I-1) | | | | | | |
| | Compound of | | | | | | |
| | formula (I-2) | | | | | | |
| | SPB-100 | | | | 15 | | |
| | XZ92741 | | | | | 15 | |
| | Compound of | | | | | | 15 |
| | formula (II-1) | | | | | | |
| Curing agent | PF-8110 | | | | | | |
| | LZ8290 | 5 | 5 | 5 | 5 | 5 | 5 |
| Curing | 2PI | | | | 0.2 | 0.2 | 0.2 |
| accelerator | 2E4MZ | 0.2 | 0.2 | 0.2 | | | |
| Elastomer | Ricon 100 | 5 | 5 | 5 | 5 | 5 | 5 |
| | Ricon 184MA6 | | | | | | |
| Filler | 525ARI | | | | | | 40 |
| | L19 | 40 | 40 | 40 | 40 | 40 | |

### 4.4. Preparation and Property Measurements of Laminates

Metal-clad laminates were prepared for Examples E1 to E12 and Comparative Examples CE1 to CE6 using the respective resin compositions. Initially, glass fiber cloths (Model No.: 2116; thickness: 0.08 mm) were impregnated with the resin compositions of Examples E1 to E12 and Comparative Examples CE1 to CE6 via roll coaters, and the thicknesses of the glass fiber cloths were controlled appropriately. These impregnated glass fiber cloths were then placed in an oven, heated, and dried at 175° C. for 2 to 15 minutes, producing semi-cured (B-stage) prepregs (with a resin content of 55%). Afterward, multiple prepregs were superimposed, and two sheets of 0.5-ounce copper foils were superimposed on the outermost layers. The prepared objects were placed in a hot-press machine to be hot-pressed using the following conditions: heating at a rate of 3.0° C./min to 200° C. to 220° C. and maintained at this temperature for 180 minutes under a full pressure of 15 kg/cm² (with an initial pressure of 8 kg/cm²).

The properties of the metal-clad laminates of Examples E1 to E12 and Comparative Examples CE1 to CE6, including coefficient of thermal expansion, heat resistance, dimensional stability, warpage performance, flame retardance, water absorption rate, drill wear, and peeling strength, were tested according to the aforementioned testing methods. The results are tabulated in Table 3 and Table 4.

TABLE 3

| | E1 | E2 | E3 | E4 | E5 | E6 | E7 | E8 | E9 | E10 | E11 | E12 |
|---|---|---|---|---|---|---|---|---|---|---|---|---|
| z-CTE (%) | 1.8 | 1.9 | 1.7 | 1.6 | 2.0 | 2.0 | 1.8 | 1.6 | 2.1 | 2.2 | 2.0 | 1.8 |
| Heat | >60 | >60 | >60 | >60 | >60 | >60 | >60 | >60 | >60 | >60 | >60 | >60 |
| resistance | | | | | | | | | | | | |
| (min) | | | | | | | | | | | | |
| Dimensional | 200 | 250 | 230 | 260 | 210 | 245 | 240 | 190 | 285 | 270 | 260 | 220 |
| stability | | | | | | | | | | | | |
| (ppm/° C.) | | | | | | | | | | | | |
| Warpage | 8 | 12 | 11 | 13 | 11 | 12 | 11 | 7 | 14 | 9 | 10 | 11 |
| (%) | | | | | | | | | | | | |
| UL-94 | V0 | V0 | V0 | V0 | V0 | V0 | V0 | V0 | V0 | V0 | V0 | V0 |
| grade | | | | | | | | | | | | |
| Water | 0.51 | 0.47 | 0.50 | 0.45 | 0.40 | 0.48 | 0.50 | 0.54 | 0.59 | 0.51 | 0.55 | 0.52 |
| absorption | | | | | | | | | | | | |
| rate (%) | | | | | | | | | | | | |
| Drill wear | 50 | 51 | 50 | 55 | 50 | 52 | 45 | 47 | 45 | 46 | 51 | 60 |
| (%) | | | | | | | | | | | | |
| Peeling | 5.0 | 4.5 | 4.9 | 4.7 | 4.8 | 4.7 | 4.7 | 5.3 | 4.8 | 4.9 | 4.5 | 4.6 |
| strength | | | | | | | | | | | | |
| (lbf/in) | | | | | | | | | | | | |

TABLE 4

| | CE1 | CE2 | CE3 | CE4 | CE5 | CE6 |
|---|---|---|---|---|---|---|
| z-CTE (%) | 2.2 | 3.5 | 3.0 | 3.2 | 2.8 | 2.5 |
| Heat resistance (min) | >60 | 15 | 40 | 55 | 50 | 30 |
| Dimensional stability | 230 | 700 | 600 | 400 | 350 | 300 |
| (ppm/° C.) | | | | | | |
| Warpage (%) | 15 | 30 | 25 | 34 | 28 | 15 |
| UL-94 grade | V0 | V1 | V0 | V1 | V0 | V0 |
| Water absorption rate | 0.58 | 0.59 | 0.70 | 0.75 | 0.80 | 0.55 |
| (%) | | | | | | |
| Drill wear (%) | 75 | 50 | 48 | 70 | 68 | 72 |
| Peeling strength | 3.0 | 2.5 | 3.5 | 3.9 | 4.2 | 4.5 |
| (lbf/in) | | | | | | |

As shown in Table 3 and Table 4, the metal-clad laminates prepared using the resin compositions of the present invention exhibit outstanding properties in coefficient of thermal expansion, heat resistance, dimensional stability, warpage performance, flame retardance, water absorption rate, drill wear, and peeling strength. In contrast, the Comparative Examples show that the metal-clade laminates prepared without all components of epoxy resin (A), maleimide-triazine resin (B) and first flame retardant (C) having the structure of formula (I) fail to exhibit these excellent properties simultaneously.

Specifically, Comparative Example CE1 shows that when the epoxy resin (A) was not used, the prepared metal-clad laminate exhibited poor drill wear and peeling strength. Comparative Example CE2, the absence of the maleimide-triazine resin (B) results in poor coefficient of thermal expansion, heat resistance, dimensional stability, warpage performance, and peeling strength. Comparative Example CE3 shows that the absence of a flame retardant leads to poor performance in several properties, especially an extremely high water absorption rate, speculated to arise from the presence of a polar maleimide-triazine resin in the epoxy resin system. Comparative Examples CE4-CE6 show that replacing the first flame retardant (C) with a conventional flame retardant prevents the prepared metal-clade laminates from exhibiting the aforementioned excellent properties simultaneously.

The above examples illustrate the principle and efficacy of the present invention and show its inventive features. People skilled in this field may proceed with various modifications and replacements based on the disclosures and suggestions of the invention as described without departing from the principle thereof. Therefore, the scope of protection of the present invention is as defined in the claims as appended.

What is claimed is:

1. A resin composition, which comprises:
(A) an epoxy resin;
(B) a maleimide-triazine resin; and
(C) a first flame retardant having a structure of formula (I): 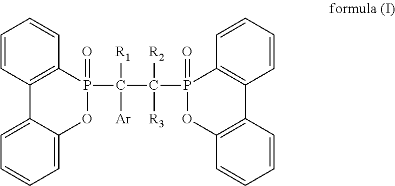
wherein,
Ar is a C₃ to C₁₈ heteroaryl or a C₆ to C₁₈ aryl;
R₁ is H or a C₁ to C₁₈ alkyl; and
R₂ and R₅ are independently H, a C₁ to C₁₈ alkyl, a C₃ to C₁₈ heteroaryl, or a C₆ to C₁₈ aryl.

2. The resin composition of claim 1, wherein the weight ratio of the first flame retardant (C) to the maleimide-triazine resin (B) is 1:6 to 5:2.

3. The resin composition of claim 1, wherein the epoxy resin (A) is selected from the group consisting of a bisphenol epoxy resin, a phenolic epoxy resin, a diphenylethylene epoxy resin, a triazine skeleton-containing epoxy resin, a fluorene skeleton-containing epoxy resin, a triphenol methane epoxy resin, a xylylene epoxy resin, a biphenyl epoxy resin, a biphenyl aralkyl epoxy resin, a naphthalene epoxy resin, a dicyclopentadiene (DCPD) epoxy resin, an alicyclic epoxy resin, and combinations thereof.

4. The resin composition of claim 1, wherein the maleimide-triazine resin (B) is obtained by reacting a maleimide compound with a cyanate ester compound.

5. The resin composition of claim 4, wherein the maleimide compound is a bismaleimide compound.

6. The resin composition of claim 4, wherein the cyanate ester compound is a compound having two or more cyanate groups.

7. The resin composition of claim 6, wherein the cyanate ester compound is an aromatic compound having two or more cyanate groups directly bonded to aromatic ring(s).

8. The resin composition of claim 1, wherein the first flame retardant (C) is selected from the group consisting of 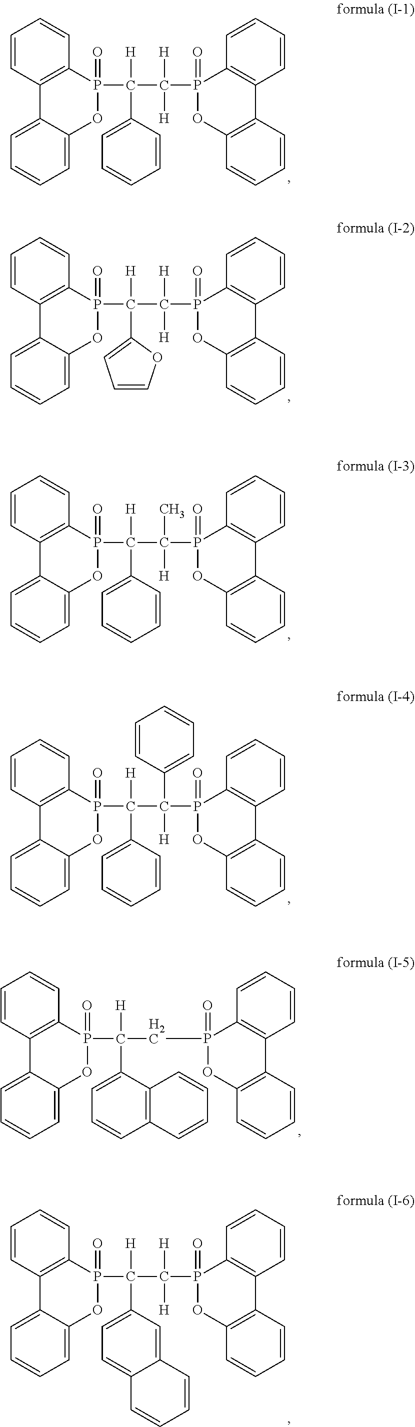 [SMILES: O=P1(CC(c2ccccc2)P2(=O)Oc3ccccc3-c3ccccc32)Oc2ccccc2-c2ccccc21 ; O=P1(CC(c2ccco2)P2(=O)Oc3ccccc3-c3ccccc32)Oc2ccccc2-c2ccccc21 ; CC(C(c1ccccc1)P1(=O)Oc2ccccc2-c2ccccc21)P1(=O)Oc2ccccc2-c2ccccc21 ; O=P1(C(c2ccccc2)C(c2ccccc2)P2(=O)Oc3ccccc3-c3ccccc32)Oc2ccccc2-c2ccccc21 ; O=P1(CC(c2cccc3ccccc23)P2(=O)Oc3ccccc3-c3ccccc32)Oc2ccccc2-c2ccccc21 ; O=P1(CC(c2ccc3ccccc3c2)P2(=O)Oc3ccccc3-c3ccccc32)Oc2ccccc2-c2ccccc21]
and combinations thereof.

9. The resin composition of claim 1, further comprising a curing agent selected from the group consisting of a cyanate ester resin, a benzoxazine resin, a phenol novolac (PN) resin, a styrene maleic anhydride (SMA) resin, dicyandiamide (Dicy), diaminodiphenyl sulfone (DDS), an amino triazine novolac (ATN) resin, diaminodiphenylmethane, a styrene-vinylphenol copolymer, and combinations thereof.

10. The resin composition of claim 1, further comprising a curing accelerator selected from the group consisting of an imidazole compound, a pyridine compound, and a combination thereof.

11. The resin composition of claim 1, further comprising an elastomer selected from the group consisting of polybutadiene, a styrene-butadiene copolymer, a styrene-butadiene-divinylbenzene copolymer, polyisoprene, a styrene-isoprene copolymer, an acrylonitrile-butadiene copolymer, an acrylonitrile-butadiene-styrene copolymer, a functional modified derivative of the preceding compounds, and combinations thereof.

12. The resin composition of claim 1, further comprising a filler selected from the group consisting of silica, aluminum oxide, magnesium oxide, magnesium hydroxide, calcium carbonate, talc, clay, aluminum nitride, boron nitride, aluminum hydroxide, silicon aluminum carbide, silicon carbide, sodium carbonate, titanium dioxide, zinc oxide, zirconium oxide, quartz, diamond, diamond-like carbon, graphite, calcined kaolin, pryan, mica, hydrotalcite, polytetrafluoroethylene (PTFE) powders, glass beads, ceramic whiskers, carbon nanotubes, nanosized inorganic powders, and combinations thereof.

13. A prepreg, which is prepared by impregnating a substrate with the resin composition of claim 1 or by coating the resin composition of claim 1 onto a substrate and drying the impregnated or coated substrate.

14. A metal-clad laminate, which is prepared by laminating the prepreg of claim 13 and a metal foil.

15. A printed circuit board, which is prepared from the metal-clad laminate of claim 14.

16. A metal-clad laminate, which is prepared by coating the resin composition of claim 1 onto a metal foil and drying the coated metal foil.

17. A printed circuit board, which is prepared from the metal-clad laminate of claim 16.
